(19) United States
(12) Patent Application Publication
(10) Pub. No.: US 2025/0174520 A1
(43) Pub. Date: May 29, 2025

(54) THERMO-MECHANICAL DEVICE FOR COMPUTING SYSTEM

(71) Applicant: XILINX, INC., San Jose, CA (US)

(72) Inventors: Gamal REFAI-AHMED, Santa Clara, CA (US); Edward C. PRIEST, Palo Alto, CA (US); Chi-Yi CHAO, Shenzhen (CN); Suresh RAMALINGAM, Fremont, CA (US); Md Malekkul ISLAM, Santa Clara, CA (US)

(21) Appl. No.: 18/953,281

(22) Filed: Nov. 20, 2024

(30) Foreign Application Priority Data
Nov. 23, 2023 (WO) PCT/CN2023/133774

(51) Int. Cl. H01L 23/46; H01L 23/433; H01L 23/52; H01L 25/065

(52) U.S. Cl. CPC H01L 23/46; H01L 23/4338; H01L 23/52; H01L 25/0655

(57) ABSTRACT

Disclosed herein are thermal management devices and electronic devices that utilized a plurality of plunger assemblies to route heat efficiently from chip packages. In some examples, the thermal management devices may also be used in electronic devices to route heat efficiently from power delivery layer residing below chip packages. In one example, a thermal management device is provided that includes a plurality of plunger assemblies retained to a metal plate. Each plunger assembly includes a metal body extending normally through an aperture formed between first and second sides of the plate and a spring biasing a distal end of the metal body away from the second side of the plate.

### CROSS-REFERENCE TO RELATED APPLICATIONS

This application claims benefit to International Patent Application No. PCT/CN2023/133774, filed Nov. 23, 2023, the contents of which are herein incorporated by reference in its entirety.

### TECHNICAL FIELD

Embodiments of the present invention generally relate to electronic devices with one or more thermal buses disposed below one or more chip packages, and in particular, electronic devices having a thermal bus dispose below a printed circuit board that provides a heat transfer path from below a chip package to a thermal management device disposed on top of the chip package that laterally by-passes the chip package.

### BACKGROUND

Electronic devices, such as tablets, computers, copiers, digital cameras, smart phones, control systems, automated teller machines, data centers, artificial intelligence system, and machine learning systems among others, often employ electronic and/or photonics components which leverage chip package assemblies for increased functionality and higher component density. Conventional chip packaging schemes often utilize a package substrate, often in conjunction with a through-silicon-via (TSV) interposer substrate and/or other such as FanOut and/or Silicon Bridging and/or substrate with glass and/or Si and/or organic core, to enable a plurality of integrated circuit (IC) dies to be mounted to a single package substrate. The IC dies are mounted to a die side (i.e., top surface) of the package substrate while a ball side (i.e., bottom surface) of the package substrate is mounted to a printed circuit board (PCB). The IC dies may include memory, logic or other IC devices. In many modern devices, one or more of the IC dies of the chip package are stacked one on top of the other to form a chip stack, which shortens routing and allows more IC dies to be utilized in the same foot print of the chip package.

Chip packages include or be configured as silicon on wafer, glass with metal routing, or organic core and/or organic substrate with metal routing, silicon with metal routing. Substrates can include an organic core having metal layers on the top and bottom. Generally, next generation package sizes can exceed 100 mm×100 mm, and have power levels that can exceed 2 KW. This large size and high power create both thermal management and warpage control challenges. Thermal management solutions must establish excellent thermal contact while considering mechanical stress prevention. Thermal management solutions should also account for mechanical warpage on the silicon surface and address both thermal management and mechanical solutions for effective and reliable power delivery.

Conventional thermal management solutions generally involve establishing a surface plane that maintains good contact with a single device which exhibits high heat flux and good power dissipation. The remaining components can be in contact with the plane through thicker thermal pads to accommodate mechanical tolerances. Alternatively, when multiple devices have high heat dissipation, different metal planes may be used to address mechanical tolerances, however, this technique can compromise thermal performance. Unfortunately, conventional thermal solutions are not effectively feasible for most silicon on wafer (SoW), system on panel (SoP), system on organic substrate with bridging (either embedded or exposed silicon bridging to establish close proximity between active devices such as IC dies and or photonics) applications where it is necessary to establish contact across the entire surface of the SoW.

Therefore, a need exists for electronic devices having improved heat management structures for chip packages.

### SUMMARY

Disclosed herein are thermal management devices and electronic devices that utilized a plurality of plunger assemblies to route heat efficiently from chip packages with little to no additional stress. In some examples, thermal management devices may also be used in electronic devices to route heat efficiently from a power delivery layer residing below the chip package, thereby reducing the thermal load required to pass through the chip package itself.

In one example, a thermal management device is provided that includes a plurality of plunger assemblies retained to a metal plate. Each plunger assembly includes a metal body extending normally through an aperture formed between first and second sides of the metal plate. A spring disposed on a first side of the metal plate and operable to bias a distal end of the metal body away from the second side of the plate.

In some examples, the metal plate includes a coolant channel routed on and/or through the metal plate. The coolant channel may be optionally routed between two adjacent plunger assemblies of the plurality of plunger assemblies. The coolant channel may be optionally routed in contact with a first plunger assembly of the plunger assemblies. In still some examples, the coolant channel may optionally be at least partially disposed in the first plunger assembly.

In another example, an electronic device is provided. The electronic device includes a first thermal management device disposed adjacent a first side of a computing layer. The first thermal management device includes a plurality of plunger assemblies retained to a metal plate. Each plunger assembly includes a metal body extending normally through an aperture formed between first and second sides of the plate and a spring biasing a distal end of the metal body away from the second side of the plate.

In some examples, the computing layer includes a plurality of integrated circuit dies disposed on a substrate. The plurality of integrated circuit dies disposed on the first side of the computing layer and facing the first metal plate.

In some examples, electronic device includes a second thermal management device disposed adjacent the second side of the computing layer. The second thermal management device includes a plurality of second plunger assemblies retained to a second metal plate. Each second plunger assembly including a metal body extending normally through an aperture formed through the second metal plate, and a spring biasing a distal end of the body away from a first side of the second metal plate and into contact with the second side of the computing layer.

In some examples, the electronic device includes a power delivery layer separated from the second side of the computing layer by a second thermal management device. The power delivery layer has a plurality of electrical routings coupled to integrated circuits present in the computing layer through the second thermal management device.

In some examples, the electronic device includes a signal delivery layer separated from the second side of the computing layer by a second thermal management device. The signal delivery layer has a plurality of electrical routings coupled to integrated circuits present in the computing layer through the second thermal management device.

In yet another example, the electronic device includes a housing having an interior volume accessible via a plurality of slots, wherein the first thermal management device disposed in the interior volume. An expansion card is disposed through one of the plurality of slots. The expansion card has the computing layer mounted thereto. The plunger assemblies of the first thermal management device are configured to engage the computing layer when the expansion card positioned extends into the interior volume.

In still yet another example, a method for cooling an electronic device is provided. The method includes contacting a first side of a computing layer via a first plurality of plunger assemblies extending through a first plate; and transferring heat from the computing layer via the first plurality of plunger assemblies to a coolant circulating through the first plate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of one example of an electronic device that includes a thermal management device interfaced with a compute layer, the compute layer including at least one chip package.

FIG. 2 is a schematic sectional view of another example of a plunger that may be utilized in the electronic device depicted in FIG. 1, among others.

FIG. 3 is a schematic plan view of a metal plate illustrating one example of a distribution of plungers across the metal plate.

FIG. 4 is a schematic sectional view of another example of a plunger that may be utilized in the electronic device depicted in FIG. 1, among others.

FIG. 5 is another schematic sectional view of the plunger of FIG. 4.

FIG. 6 is a schematic sectional view of one example of an electronic device that includes a thermal management device interfaced with a compute layer.

FIG. 7 is a schematic sectional view of one example of an electronic device having thermal management devices disposed on opposite sides of a compute layer.

FIG. 8 is a schematic sectional view of one example of an electronic device having thermal management devices disposed on opposite sides of a compute layer with an underlying a power delivery layer.

FIG. 9 is a schematic sectional view of one example of an electronic device having an enclosure that has at least one or more thermal management devices that can interface with compute layers removably installed in the enclosure.

FIGS. 10A and 10B are schematic partial sectional views of one example of an electronic device 140 having an enclosure 910 that has at least one or more thermal management devices 120 that can interface with compute layers 110 removably installed in the enclosure 910. The compute layers 110 are disposed on a.

FIG. 11 is a schematic diagram of a method for cooling an electronic device.

FIG. 12 is a schematic diagram of a method for cooling an electronic device disposed in an enclosure.

To facilitate understanding, identical reference numerals have been used, where possible, to designate identical elements that are common to the figures. It is contemplated that elements of one embodiment may be beneficially incorporated in other embodiments.

### DETAILED DESCRIPTION

As discussed above, the size and power of next generation electronic devices have integrated circuit dies and power delivery systems that are difficult to cool and pose problems for maintaining the planarity required to ensure robust electrical connections and lasting performance. Disclosed herein are thermal management devices and electronic devices that utilized a plurality of plunger assemblies to route heat efficiently out of chip packages, thus enabling the reliable use of high power integrated circuits while still maintaining good warpage resistance. The thermal management devices described herein leverage spring loaded plungers to route heat efficiently away from heat generating components such as integrated circuit dies, surface mounted passive devices, and power delivery layers. The plungers ensure good contact for effective heat transfer, while being mechanically decoupled from the chip package itself, thus promoting good heat transfer without inducing undesired stress.

The plungers of thermal management devices described herein provide excellent thermal contact with a large surface area of silicon without creating undesirable amounts mechanical stress. Thus, the thermal management device provides a significant advancement over conventional techniques as efficient heat dissipation is enabled without compromising the structural integrity of the electronic device. Additionally, the thermal management solution provided by the thermal management device is scalable and can be applied to silicon areas of just about any size, thereby offering exceptional versatility and adaptability. Moreover, this thermal management techniques described herein can be extended to accommodate multiple active high power thermal management devices, thus allowing for effective thermal management across a large surface area of a printed circuit board. This holistic approach addresses the challenges of thermal contact and power dissipation in a comprehensive and innovative manner.

In one example, a thermal management device is provided that includes a plurality of plunger assemblies retained to a metal plate. Each plunger assembly includes a metal body extending normally through an aperture formed between first and second sides of the plate, and a spring biasing a distal end of the metal body away from the second side of the metal plate. The advantage of this innovative plunger solution is the ability to extend the cooling limit of an electronic device, while effectively managing mechanical stresses. By decoupling mechanical tolerances and coupling advanced thermal techniques, the plunger assembly based thermal management device provides a scalable thermal solution that can be applied to just about any surface area. Advantageously, regardless of the system's size or complexity, the thermal management device can efficiently regulate temperature and maintain optimal performance.

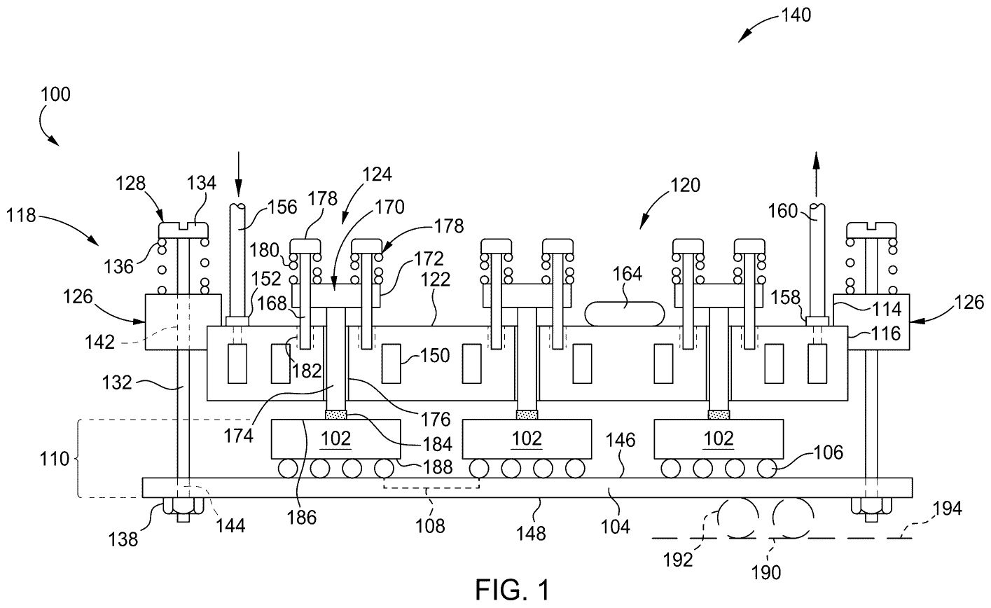

Turning now to FIG. 1, a schematic sectional view of an electronic device 140 that includes one or more chip packages 100 mounted to a printed circuit board (PCB) 190 is illustrated. The chip package 100 is interfaced with at least one thermal management device 120. The chip package 100 includes at least one integrated circuit (IC) die 102 and a package substrate 128. The IC die 102 is mounted to a top surface 146 of the package substrate 128. The chip package 100 can be configured in heterogeneous integration with several chiplet and/or optical devices. Optionally, an interposer (not shown) may be disposed between the IC die 102 and the package substrate 128. The package substrate 128 of the chip package 100 may be mounted on a top surface 194 of the PCB 190, for example using a socket or solder balls 192, to form the electronic device 140.

One or more of the IC dies 102 may be configured as a surface mounted component, such as a voltage regulator, a voltage converter, a resistor, a capacitor, an inductor, and a transformer or other surface mounted passive or active device. The surface mounted component is connected to the functional circuitry of the IC die 102 via package routing formed through the package substrate 128.

Continuing to refer to FIG. 1, each IC die 102 of the chip package 100 includes functional circuitry. The functional circuitry may include block random access memory (BRAM), UltraRAM (URAM), digital signal processing (DSP) blocks, configurable logic elements (CLEs), and the like. The IC die 102 may be, but is not limited to, programmable logic devices, such as field programmable gate arrays (FPGA), memory devices, such as high band-width memory (HBM), optical devices, processors or other IC logic structures. The IC die 102 may optionally include optical devices such as photo-detectors, lasers, optical sources, and the like. The IC die 102 may also be configured as a processor that includes central processing unit (CPU) cores. As such, the IC die 102 may be referred to as a CPU die or CPU chiplet. The functional circuitry of the IC die 102 may also include System Management Unit (SMU). The SMU is circuitry configured to monitor thermal and power conditions and adjust power and cooling to keep the IC die 102 functioning as within specifications. The functional circuitry of the IC die 102 may also include Dynamic Function exchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry of IC die 102 may include accelerated compute cores. As such, the IC die 102 may be referred to as an accelerator die or accelerator chiplet. The IC die 102 may also be referred to as a graphic processing unit (GPU) die or GPU chiplet. The accelerated compute cores contained in the functional circuitry of the IC die 102 generally includes math engine circuitry. The math engine circuitry is generally designed for task specific computing, such as used data center computing, high performance computing and AI/ML computing. Along with the accelerated compute cores, functional circuitry of the IC die 102 may also include SMU circuitry and DFX circuitry. In the example of FIG. 1, the IC die 102 is a logic die having math processor (also known as math engine) circuitry for accelerating machine-learning math operations in hardware, such as self-driving cars, artificial intelligence and data-center neural-network applications.

In one example, all of the IC dies 102 within the chip package 100 are the same type. In other examples, one or more of the IC dies 102 within the chip package 100 are different types. When a plurality of IC dies 102 are utilized, the IC dies 102 may be disposed in a vertical stack and/or disposed laterally side by side. Although three IC dies 102 are shown in FIG. 1, the number of IC dies 102 disposed in the chip package 100 may vary from one to as many as can fit within the chip package 100. Additionally, one or more of the IC dies 102 may optionally be configured as a chiplet.

Each IC die 102 includes a die body having a die bottom surface 188 and a die top surface 186 connected by the die sidewalls. The functional circuitry is disposed within the die body and includes routing that terminates on the die bottom surface 188 of the IC die 102. In the example depicted in FIG. 1, the functional circuitry of the IC die 102 is electrically and mechanically coupled to package circuitry 108 formed in the package substrate 128 by the interconnects 106. In one example, the interconnects 106 are solder connections, such as solder bumps. The interconnects 106 may alternatively be formed by a hybrid bond layer or other suitable technique.

The package substrate 128 generally includes at least an upper build-up layer disposed on a core. Optionally, a lower build-up layer may be disposed on the other side of the core from the upper build-up layer. The build-up layers includes a plurality of conductive layers and vias that are patterned to provide routing comprising a portion of the package circuitry 108. One end of the package circuitry 108 formed in the upper build-up layer terminates at bond pads formed on a top surface 146 of the package substrate 128 where the package circuitry 108 connects to the contact pads of the IC die 102 through the interconnects 106. The other end of the package circuitry 108 formed in the package substrate 128 terminates at bond pads formed on the bottom surface 148 of the package substrate 128.

Solder balls 192 are formed on the bond pads exposed on the bottom surface 148 of the package substrate 128. The solder balls 192 connect the package circuitry 108 to circuitry of the PCB 190 that terminates at the top surface 194 of the PCB 190. Alternatively, the chip package 100 may be coupled to the top surface 194 of the PCB 190 via a socket. The circuitry of the PCB 190 may also connect the functional circuitry of the IC die 102 to a power, ground or signal source exterior to the electronic device 140 through a PCB connector, such as a backplane connector, audio/video connector, card edge connector, and the like.

Turning now to the thermal management device 120, the thermal management device 120 generally conducts heat away from the die top surface 186 of the IC die 102. A layer of thermal interface material (TIM) 184 may be disposed at the interface between the thermal management device 120 and the IC die 102 to enhance heat transfer therebetween. The TIM 184 may be thermal grease, liquid metal, thermal pad or other suitable material that enhances the heat transfer between the IC die 102 and the thermal management device 120.

The thermal management device 120 generally includes a metal plate 122 and a plurality of plunger assemblies 124. The metal plate 122 is generally formed from a metal material having good heat transfer properties, such as aluminum, stainless steel and copper, among others. The metal plate 122 may be fabricated from a single mass of material, or from multiple components that are assembled together in a manner that allows good heat transfer across the metal plate 122. Although not shown, thermal management device 120 may include one or more heat transfer devices 164. The heat transfer devices 164 may be at least one or both of an active or passive heat transfer device. Examples of active heat transfer devices 164 includes thermoelectric coolers, forced air heat exchangers, forced liquid heat exchangers, and the like. Examples of passive heat transfer devices 164 includes vapor chambers, heat pipes, phase change materials, fins, and the like. In the example depicted in FIG. 1, the heat transfer device 164 is a heat pipe disposed on the top surface of the metal plate 122. In yet another example, the plunger assembly 124 includes a heat transfer device 164 in the form of a heat pipe embedded therein.

The metal plate 122 includes one or more channels 150 formed on or through the metal plate 122. The channels 150 are configured flow coolant therethrough, thus removing heat metal plate 122 such that the metal plate 122 operates as a heat sink for the IC dies 102 and other heat generating components of the chip package 100. In some examples, the channel 150 may have portions disposed on the metal plate 122 and other portions disposed in the metal place 122. In FIG. 1, a single internal channel 150 is formed through the metal plate 122. One end of the channel 150 terminates at an inlet port 152, while the other end of the channel 150 terminates at an outlet port 158. The inlet port 152 is coupled to a remote coolant source or remote heat exchanger by a supply line 156. The supply line 156 provides coolant, such as a heat transfer fluid, to the channel 150 that circulates the coolant through the metal plate 122, eventually exiting the metal plate 122 through the outlet port 158 where the coolant is carried away through an outline line 160. The coolant is utilized to remove heat transmitted through the plunger assemblies 124 from the IC dies 102 from the metal plate 122.

The metal plate 122 includes a plurality of apertures 176. A portion of the plunger assemblies 124 extend through the apertures 176 to contact the IC dies 102 and/or other portions of the chip package 100.

Each plunger assembly 124 includes a plunger 170 and a biasing assembly 178. The biasing assembly 178 provides a force that urges the plunger 170 against the heat generating components of the chip package 100, such as the IC dies 102.

The plunger 170 includes an elongated body 174 and a head 172. The elongated body 174 and the head 172 are generally fabricated from a highly thermally conductive material, such as a metal. Metals suitable for fabricating the elongated body 174 and the head 172 include aluminum, stainless steel and copper, among others. One end of the elongated body 174 is coupled to the head 178 while the distal end of the elongated body 174 extends through the aperture 176 formed in the metal plate 122 beyond the bottom surface of the metal plate 122.

The elongated body 174 is sized to freely move within the aperture 176 of the metal plate 122, but still allow for good heat transfer between the plunger 170 and metal plate 122. The distal end of the elongated body 174 is urged by the biasing assembly 178 the bottom surface of the metal plate 122 and against the top surface 186 of the IC die 102. As discussed above, TIM 184 may be disposed between the distal end of the elongated body 174 and the top surface 186 of the IC die 102 to promote good heat transfer therebetween. The elongated body 174 may also include a heat pipe 164 embedded therein.

The biasing assembly 178 generally provides a force that urges the plunger 170 towards the chip package 100. In one example, the biasing assembly 178 includes a spring 180 that is captured between the head 172 of the plunger 170 and a head 178 of a fastener 168. The spring 180 may be a coil spring, a flat spring, a compressed elastomer, or other suitable device. The fastener 168 extends through a hole formed through the head 172 of the plunger 170, and is secured in a threaded hole 182 formed in the top surface of the metal plate 122. The fastener 168 can be tightened to control the compression of the spring 180, and thus, control the force that the spring 180 generates to urge the plunger 170 against the IC die 102. The threaded connection between the fastener 168 and metal plate 122 also helps transfer heat from the head 172 of the plunger 170 to the metal plate 122, thus enhancing the cooling and thermal management of the IC dies 102 and other components of the chip package 100.

The thermal management device 120 is secured to the chip package 100 via a retaining assembly 118. The retaining assembly 118 includes a frame 126 and biasing connector 128. The frame 126 includes an inside perimeter 114 having a notch 116. The notch 116 is sized to receive an outer perimeter corner of the metal plate 122, such that the frame 126 and metal plate 122 securely mate.

The biasing connector 128 generally includes a fastener 132 and a spring 136. The biasing connector 128 generally provides a force that urges the thermal management device 120 towards the chip package 100. In one example, the biasing connector 128 includes a spring 136 that is captured between the top of the frame 126 and a head 134 of a fastener 132. The fastener 132 extends through a hole formed through the frame 126 and a hole formed in either or both of the package surface 104 and PCB 190, and is engaged with nut 138. The nut 138 can be tightened on the nut 138 to control the compression of the spring 136, and thus, the force that the spring 136 exerts on the frame 126. The force exerted on the frame 126 is transferred to the thermal management device 120, while ultimately controls the force exerted by the thermal management device 120 against the IC die 102.

Thus in operation, heat generated by the IC die 102 is transferred through the TIM 184 to the distal end of the plunger 170. Heat is then transferred from the plunger 170 to the metal plate 122. Heat is transferred from the metal plate 122 by coolant circulating through the channels 150 formed in the metal plate 122. As the force utilized to secure the metal plate 122 to the substrate 104 (i.e., the force generated by the spring 136) is decoupled from the force urging the plungers 170 against the IC dies 102 (i.e., the force generated by the spring 180), the stress applied to the chip package 100 by the thermal management device 120 is negligible. As a result, high heat transfer capacity is achieved without significant contribution to warpage of the chip package 100. Consequently, the chip package 100 can provide high performance with high powered IC dies 102 in a reliable and robust manner.

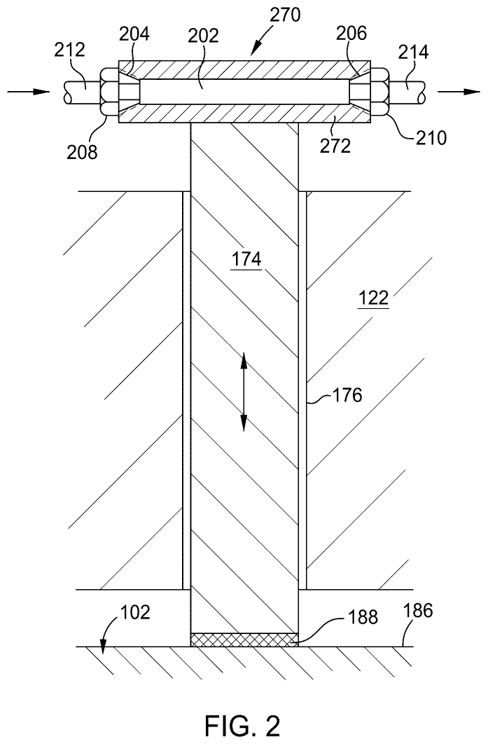

FIG. 2 is a schematic sectional view of another example of a plunger 270 that may be utilized in the plunger assembly 124 of the thermal management device 120 depicted in FIG. 1, among others. A biasing assembly 178 is integrated with the plunger 270 to form a plunger assembly that is essentially the same of the plunger assembly 124 described above. However, in FIG. 2, the biasing assembly 178 is not shown to better enable a fluid passage 202 formed in the plunger 270 to be more clearly shown.

The plunger 270 generally includes a head 272 attached to an elongated body 174. The elongated body 174 and the head 272 are generally fabricated from a highly thermally conductive material, such as a metal. Similar to as described above, the distal end of the elongated body 174 extends through the aperture 176 formed in the metal plate 122 and contacts the top surface 186 of the IC die 102. As discussed above, TIM 184 may be disposed between the distal end of the elongated body 174 and the top surface 186 of the IC die 102 to promote good heat transfer therebetween.

The head 272 include an inlet port 204 and an outlet port 206 that are fluidly coupled to the fluid passage 202 formed in the head 272 of the plunger 270. A fitting 208 is disposed in the inlet port 204. The fitting 208 is connected to a tube 212 that provides coolant to the fluid passage 202. The tube 212 is connected to a coolant source either directly, or indirectly through the channels 150 formed in the metal plate 122. A fitting 210 is disposed in the outlet port 206. The fitting 210 is connected to a tube 214 that receives the coolant exiting the fluid passage 202. The tube 214 may be routed back to the coolant source or other heat exchanger, or to other plungers 270 within the thermal management device 120. As the coolant is directly in contact with the plunger 270, heat from the IC die 102 transferred to the head 272 through the elongated body 174, may be more efficiently removed from the IC die 102, thus enabling higher power and performance, without inducing excessive and undesirable stress on the chip package 100.

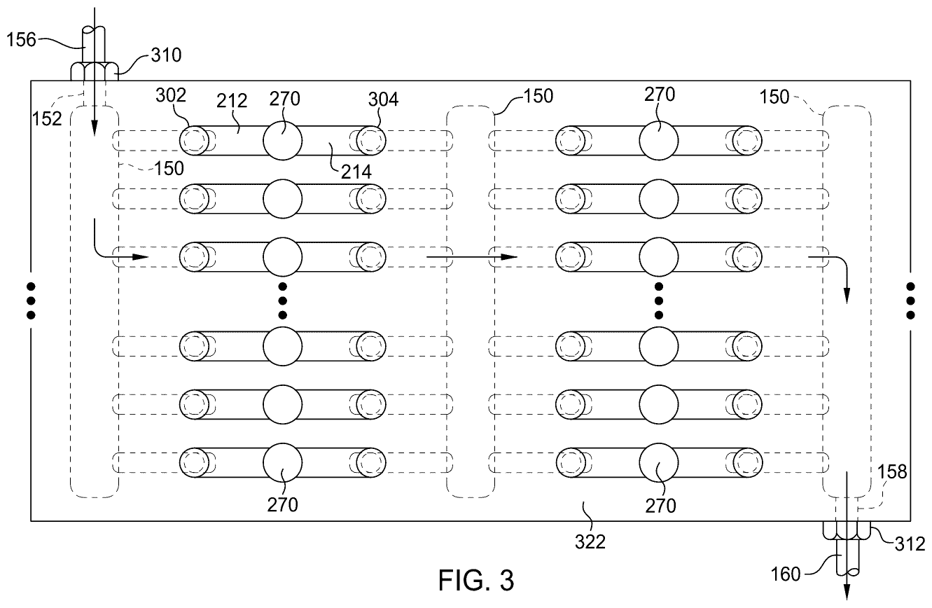

FIG. 3 is a schematic plan view of a metal plate 322 illustrating one example of a distribution of plungers 270 across the metal plate 322. The metal plate 322 is constructed similar to that of the metal plate 122 described above, except for the use of the plungers 270 to replace the plungers 170, and to routing of the coolant though the channels 150. As with FIG. 2, the plunger assemblies are illustrated by just the plungers 270, although the biasing assembly 178 is present but not shown.

In the example depicted in FIG. 3, the plungers 270 of the plungers assemblies are arranged in rows and columns. The number of rows and columns are for illustrative purposes, and any X number of rows may be used with Y number of columns, where X is a whole number equal to or greater than 1, and Y is a whole number equal to or greater than 1. X and Y may be the same or different.

The inlet port 152 formed in the metal plate 322 has a fitting 310. The fitting 310 connect the supply line 156 to the first channel 150 formed in the metal plate 322. A plurality of ports 302 are formed through the metal plate 322 and are connected to the first channel 150. The ports 302 are connected to the tubes 212 to the inlet port 204 of the plunger 270. Similarly, a plurality of ports 304 are formed through the metal plate 322 and are connect to a second channel 150 formed in the metal plate 322. The ports 304 are connected by the tubes 214 to the outlet port 206 of the plunger 270. Thus, coolant entering the metal plate 322 through the inlet port 152 flows through the first channel 150 then out of the plate 322 and through the tube 212 to the passage 202 formed in the head 272 of the plunger 270. Coolant exiting the passage 202 formed in the head 272 of the plunger 270 flows through the tube 214 to the port 304 formed in the metal plate 322 and into the second channel 150. Coolant then exits the second channel 150 and flows through the passage 202 of another plunger 270 disposed in an adjacent column of plungers 270. The coolant eventually flows into the last cavity 150 formed in the metal plate 322 where the coolant can exit through the outlet port 158. A fitting 312 connect the tube 160 to the outlet port 158.

Although FIG. 3 depicts coolant being routed in parallel across a plurality of rows of plungers 170, the coolant may be routed in other manners. For example, the coolant may be routed through each plunger 270 without passing though the metal plate 122. In another example, the coolant may be routed through one or more plungers 270 resisting in different rows of a common column prior to being routed to another plunger in a different column.

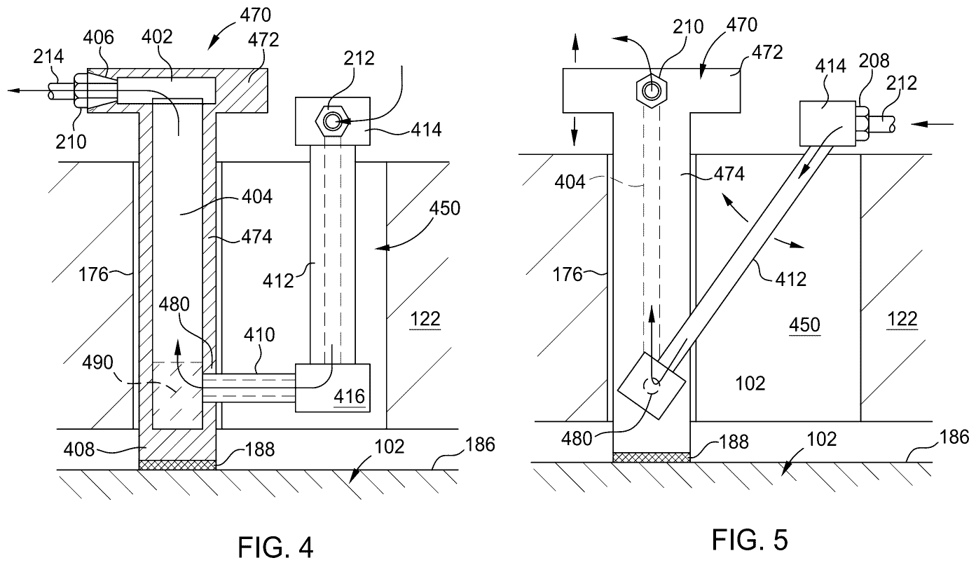

FIGS. 4 and 5 are schematic sectional views of another example of a plunger 470 that may be utilized in the plunger assembly 124 of the thermal management device 120 depicted in FIG. 1, among others. A biasing assembly 178 is integrated with the plunger 470 to form a plunger assembly that is essentially the same of the plunger assembly 124 described above. However, in FIGS. 4 and 5, the biasing assembly 178 is not shown to better enable the fluid passages 402, 404 formed through the plunger 470 to be more clearly shown.

The plunger 470 generally includes a head 472 attached to an elongated body 474. The elongated body 474 and the head 472 are generally fabricated from a highly thermally conductive material, such as a metal. Similar to as described above, a distal end 408 of the elongated body 474 extends through the aperture 176 formed in the metal plate 122 and contacts the top surface 186 of the IC die 102. As discussed above, TIM 184 may be disposed between the distal end of the elongated body 474 and the top surface 186 of the IC die 102 to promote good heat transfer therebetween.

The plunger 470 includes a passage 402 formed in the head 472 that is connected to a passage 404 formed in the elongated body 474. The passage 404 formed in the elongated body 474 has an inlet 480 proximate the distal end 408. The passage 404 may also include a porous material 490 disposed proximate the inlet 480 to disperse coolant entering the passage 404 into good contact with the metal walls of the elongated body 474 forming the plunger 470. The porous material 490 may be a sintered metal, foamed metal, metal mesh, metal wool or other thermally conductive material that allows coolant to flow therethrough. The increased surface area of the porous material 490 also improves heat transfer from the plunger 470 to the coolant. The inlet 480 is connected by a hollow tube 410 to a connector block 416. The connector block 416 is connect by a hollow tube 412 to a connector block 414. The tube 412 is flexible to allow the plunger 470 to move vertically within the aperture 176 of the metal plate 122. The connector block 414 includes an inlet port that receives the fitting 212 that connect the plunger 470 to the supply line 212.

The tubes 410, 412 and connector block 416 are disposed in a slot 450 formed in the metal plate 122. One side of the slot 450 is open to the aperture 176 to allow the tube 410 to connect to the plunger 470 disposed in the aperture 176.

The opposite end of the passage 404 is connected to the passage 402 formed in the head 472. The passage 402 in the head 472 is conned to an outlet port 406. The outlet port 406 receives the fitting 210 that connects the passage 402 to the outlet line 214.

As the coolant enters the distal end 408 of the plunger 470 proximate the IC die 102, and is routed away from IC die 102 to the head 472 and out the plunger 470, heat transfer efficiency is improved, thus enabling higher power and performance, without inducing excessive and undesirable stress on the chip package 100.

Alternatively in examples where coolant is not routed through the elongated body 474, the tube 412 may be configured as a heat transfer device 164, for example in the form of a flexible heat pipe. The flexible heat pipe allows the plunger 470 to move vertically within the aperture 176 of the metal plate 122 while promoting good heat transfer.

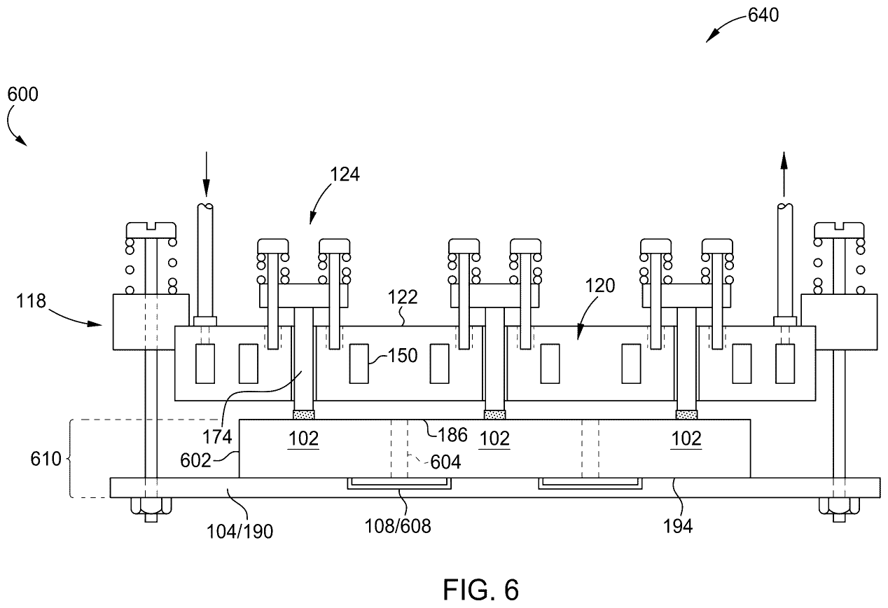

FIG. 6 is a schematic sectional view of another example of an electronic device 640 that includes a thermal management device 120 interfaced with a compute layer 610 of a chip package 600. The chip package 600 may be mounted on a top surface of a PCB 190 (as shown in FIG. 1), for example using a socket or solder balls, to form the electronic device 640 in the same manner as described with reference to the chip package 100.

The compute layer 610 generally include a plurality of IC dies 102 arranged in a common plane mounted on a package substrate 104. Optionally, the plurality of IC dies 102 of the compute layer 610 may be directly mounted on the PCB 190 without use of a package substrate 104. The compute layer 610 may be mounted to the package substrate 104 via solder interconnects, hybrid bonding or other suitable technique. The plurality of IC dies 102 of the compute layer 610 may be part of a contiguous section of a substrate (i.e., wafer, panel, glass, organic or other suitable workpiece) on which the dies were formed. The plurality of IC dies 102 may alternatively be part of a reconstituted substrate. The plurality of IC dies 102 may alternatively be secured together using a mold compound 604, as shown in FIG. 6. Although the compute layer 610 is illustrated in FIG. 6 as a single tier of IC dies 102, one or more of the IC dies 102 may have one or more tiers of IC dies stacked thereon. The IC dies 102 comprising the compute layer 610 communicate with each other via package routing 108 and/or routing 608 formed in the PCB 190.

As discussed above, the thermal management device 120 of the electronic device 640 is interfaced with the compute layer 610 of the chip package 600. The thermal management device 120 removes heat from the plurality of IC dies 102 of the compute layer 610 in the same manner as discussed above with reference to the chip package 100.

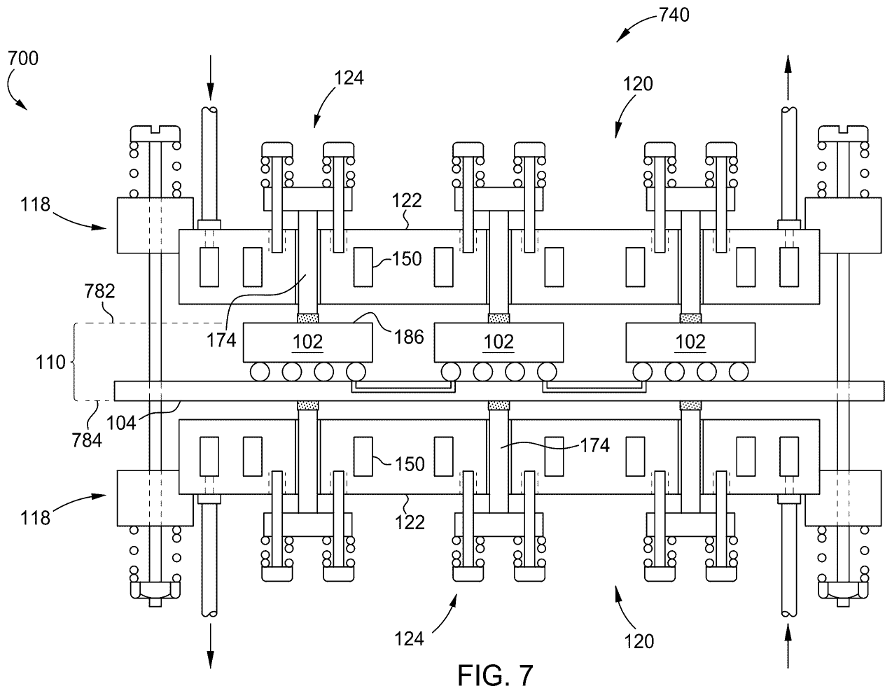

FIG. 7 is a schematic sectional view of another example of an electronic device 740 that includes thermal management devices 120 interfaced on opposite sides of a chip package 700. The chip package 700 may be mounted on a top surface of a PCB 190 (as shown in FIG. 1), for example using a socket or solder balls, to form the electronic device 740 in the same manner as described with reference to the chip package 100.

The chip package 700 includes a compute layer 110. The compute layer 110 includes generally include a plurality of IC dies 102 arranged in a common plane mounted on a package substrate 104 as described above. The compute layer 110 may be alternatively configure similar to the compute layer 610 described above, or have another suitable arrangement of IC dies 102.

The compute layer 110 includes a top surface 782 and a bottom surface 784. The top surface 782 of the compute layer 110 is interfaced with a first thermal management device 120. The management device 120 interfaces with the top surface 186 of the IC dies 102 or other component of the chip package 700 exposed on the top surface 782 of the compute layer 110. The plungers 170 of the management device 120 interface with the top surface 186 of the IC dies 102 to efficiently remove heat from the compute layer 110 of the chip package 800.

The bottom surface 784 of the compute layer 110 is interfaced with a second thermal management device 120. The first and second thermal management devices 120 thus sandwich the compute layer 110, thus removing heat from both the top and bottom surfaces 782, 784 of the compute layer 110, thereby increasing the rate of heat removal from the compute layer 110. The increased rate of heat removal from the compute layer 110 enables the reliable use of significantly higher powered IC dies 102, as compared to conventional devices that rely on heat transfer from only one side of a compute layer.

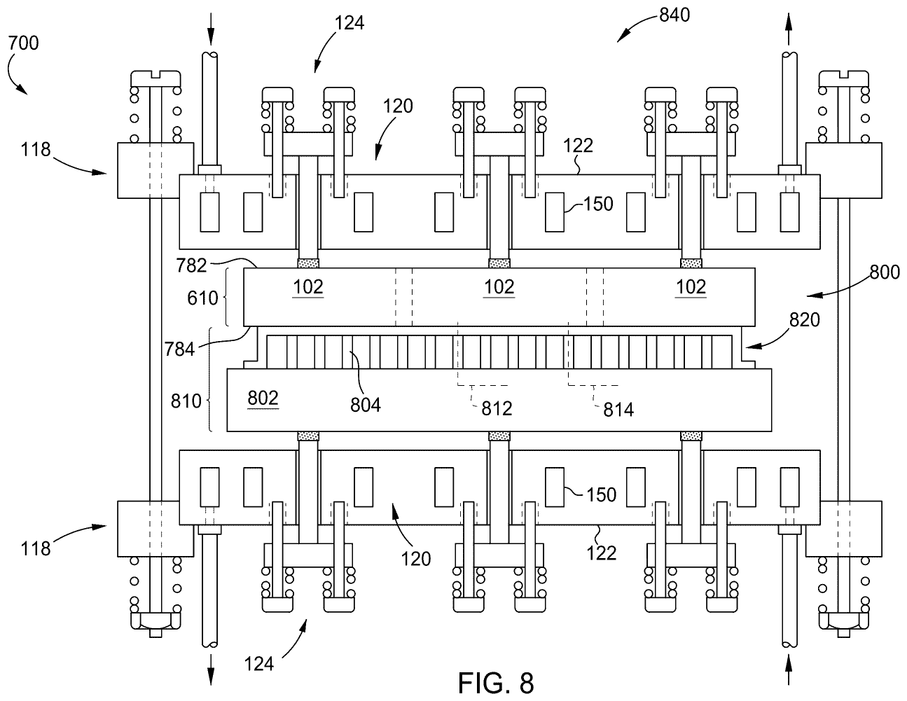

FIG. 8 is a schematic sectional view of another example of an electronic device 840 that includes thermal management devices 120 interfaced on opposite sides of a chip package 800. The chip package 800 may be mounted on a top surface of a PCB 190 (as shown in FIG. 1), for example using a socket or solder balls, to form the electronic device 640 in the same manner as described with reference to the chip package 100.

The chip package 800 includes a compute layer 110 stacked with a power delivery layer 810. The power delivery layer 810 may additionally or alternatively be a signal delivery layer. The compute layer 110 includes generally include a plurality of IC dies 102 arranged in a common plane mounted on a package substrate 104. Optionally, the plurality of IC dies 102 of the compute layer 110 may be directly mounted on the PCB 190 without use of a package substrate 104. The compute layer 110 may be alternatively configure similar to the compute layer 610 described above, or have another suitable arrangement of IC dies 102. The IC dies 102 of the compute layer 110 may be mounted to the package substrate 104 via solder interconnects, hybrid bonding or other suitable technique.

The compute layer 110 includes a top surface 782 and a bottom surface 784. The top surface 782 of the compute layer 110 is interfaced with a first thermal management device 120. The management device 120 interfaces with the top surface 186 of the IC dies 102 or other component of the chip package 800 exposed on the top surface 882 of the compute layer 110. The plungers 170 of the management device 120 interface with the top surface 186 of the IC dies 102 to efficiently remove heat from the compute layer 110 of the chip package 800.

The bottom surface 784 of the compute layer 110 is interfaced with a top surface of the power delivery layer 810. The power delivery layer 810 includes a routing layer 820 formed on a substrate 802. The substrate 802 may be configured as a package substrate or a PCB. The routing layer 820 includes a plurality of dielectric layers formed on the substrate 802. The dielectric layers of the routing layer 820 includes lines and vias patterned to form power routings 812. The power routings 812 provide power to the IC dies 102 from the bottom surface 784 of the compute layer 110. The routing layer 820 may optionally include signal routings 814 formed by the lines and vias disposed in the dielectric layers. The signal routings 814 provide signal transmission to the IC dies 102 from the power delivery layer 810 through the bottom surface 784 of the compute layer 110. The power and signal routings 812, 814 are also connected to routings formed in the substrate 802. The routings formed in the substrate 802 terminate at edge contact pads or other types of pads/connectors for communicating with other electronic devices remote from the electronic device 840.

The bottom surface of the power delivery layer 810 is interfaced with a second thermal management device 120. The first and second thermal management devices 120 thus sandwich the compute and power delivery layers 110, 810, and thus removing heat from both the top surface 782 of the compute layer 110 and the bottom surface of the power delivery layer 810, thereby increasing the rate of heat removal from the chip package 800. Additionally, as the power delivery layer 810 is external to the compute layer 110, more space is available for other devices and routings within the IC dies 102, while the heat generating power routing as located away from the IC dies 102. The increased rate of heat removal from the compute layer 110 and also the separating of the heat generating power delivery layer 810 enables the reliable use of significantly higher powered IC dies 102, as compared to conventional devices that rely on heat transfer from only one side of a compute layer, and/or have power routings predominantly located within a conventionally configured compute layer.

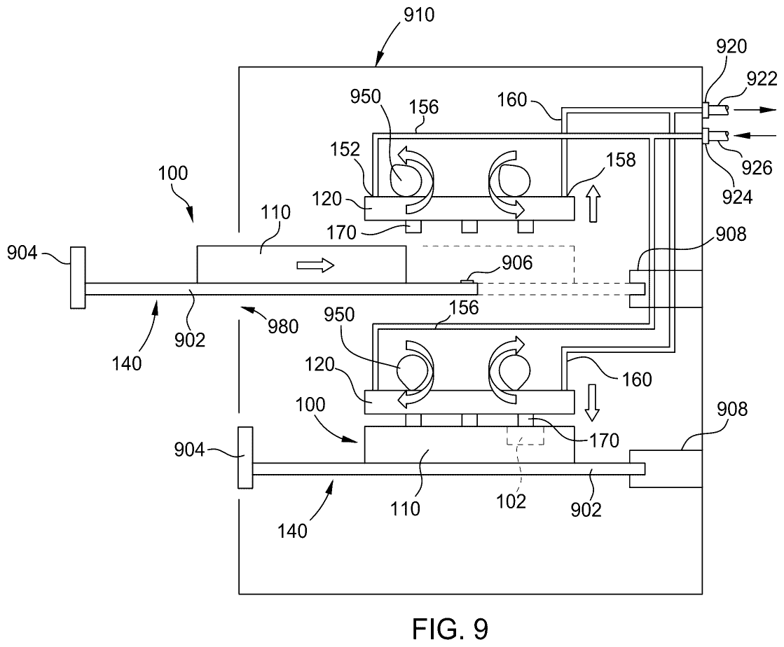

FIG. 9 is a schematic sectional view of one example of one or more electronic devices 140 removably disposed in an interior volume of an enclosure 910. In the example depicted in FIG. 9, the electronic devices 140 are configured as expansion cards or server blades, having a computing layer 110 disposed on a PCB 902. The PCB 902 may be configured as an expansion card, a server blade or other computing device. The PCB 902 may also include a bracket 904 for securing the PCB 902 to the enclosure 910 upon being fully inserted into a slot 980 of the enclosure 910.

The enclosure 910 has at least one or more thermal management devices 120 that can interface with compute layers 110 removably installed in the enclosure 910. Although only two electronic devices 140 are illustrated in FIG. 9, the number of electronic devices 140 may range from one to as many electronic devices 140 that may be suitably housed in the enclosure 910.

The enclosure 910 is generally an electronic enclosure, such as a computer or server cabinet, among others. The enclosure 910 houses the thermal management devices 120. The thermal management devices 120 in a manner that allows the thermal management devices 120 to move between a position clear of the electronic device 140, and a position in which the plungers 170 of the thermal management devices 120 are engaged with at least the computing layer 110 of the chip package 100 of the electronic devices 140. Although not shown in FIG. 9, the enclosure 910 may optionally house a second thermal management device 120 that engages a side of the chip package 100 opposite to the side engaged by the other thermal management devices 120. In one example, one thermal management device 120 engages a compute layer 110 of an electronic device 140, while a different thermal management device 120 engages the opposite side of the compute layer 110 and/or a power delivery layer 810 of the electronic device 140, such as illustrated in FIG. 8.

The inlet ports 152 of each thermal management device 120 are coupled by supply lines 156 to a common inlet port 924 of the enclosure 910. The inlet port 924 is coupled by a supply line 926 to a coolant source (not shown). Similarly, the outlet ports 158 of each thermal management device 120 are coupled by exhaust lines 160 to a common outlet port 920 of the enclosure 910. The outlet port 920 is coupled by an exhaust line 922 to the coolant source, heat exchanger or other spent coolant receptacle (not shown).

As discussed above, the thermal management devices 120 are mounted to the enclosure 910 in a manner that allows the thermal management devices 120 to move between positions clear and in contact with the electronic device 140. In the clear position (shown by the upper thermal management device 120 in FIG. 9), the electronic device 140 may be slid through a slot 980 into and out of the enclosure 910. In the inserted position (shown by the lower electronic device 140 in FIG. 9), the electronic device 140 may engage an electrical connector 908 disposed in the enclosure 910. The electrical connector 908 allows the electronic devices 140 with the enclosure 910 to communicate with one another, and communicate with other electronic devices disposed within and/or remote from the enclosure 910. The lower thermal management device 120 shown in FIG. 9 is disposed in the contact position in which the plungers 170 of the thermal management device 120 are engaged with the computing layer 110 (i.e., IC dies 102) of the chip package 100 of the inserted electronic device 140.

The enclosure 910 also includes actuators 950 that move the thermal management devices 120 between the clear and contact positions. The actuators 950 may be a lever, cam, latch, slide, linear actuator, electric motor or other suitable device that can move the plungers 170 of the thermal management device 120 into and out of contact with the adjacent electronic device 140. In the example depicted in FIG. 9, the actuator 950 is in the form of a cam that can be rotated to move the thermal management device 120 against a spring return force in a direction towards and in contact with the electronic device 140, such as in contact with the computing layer of the chip package 100 of the electronic device 140. When the cam is rotated in the opposite direction, the spring return force moves the thermal management device 120 in a direction away from and out of contact with the electronic device 140, thus enabling the electronic device 140 to move into and out of the enclosure 910 through the slot 980.

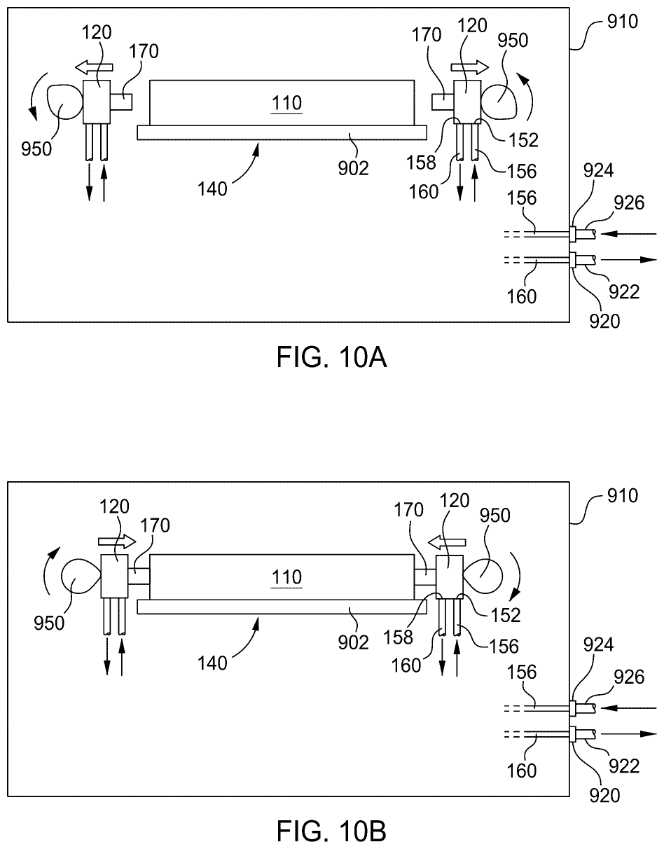

FIGS. 10A and 10B are schematic partial sectional views of one example of an electronic device 140 removably disposed in an enclosure 910 that has at least one or more thermal management devices 120 that can interface with compute layers 110 of the electronic device 140. The compute layers 110 are disposed on a PCB 902 of the electronic device 140. The PCB 902 of the electronic device 140 may be configured as an expansion card, a server blade or other computing device. The PCB 902 may also include a bracket for securing the PCB 902 to the enclosure 910 upon being fully inserted into a slot of the enclosure 910, as shown in FIG. 9. For reference, the enclosure 910 illustrated in FIGS. 10A and 10B have an orientation that is rotated 90 degrees relative to the enclosure 910 illustrated in FIG. 9, such that the PCB 902 moves into the page (for example, on the Y axis) when inserted the slot of the enclosure 910 to engage the electrical connector 908 (not shown in FIG. 10A or FIG. 10B).

In the enclosure 910 depicted in FIGS. 10A and 10B, the thermal management devices 120 are disposed to either side of the electronic device 140. The thermal management devices 120 are mounted to the enclosure 910 in a manner that allows the thermal management devices 120 to move in a lateral direction (for example, in the X axis) between positions clear and in contact with the electronic device 140. In the clear position (shown by the thermal management devices 120 depicted in FIG. 10A), the thermal management devices 120 are laterally spaced from the electronic device 140, thus allowing the electronic device 140 to move in the Y direction through the slot 980 into and out of the enclosure 910. In the inserted position (shown by the electronic device 140 in FIG. 10B), the electronic device 140 engages the electrical connector 908 disposed in the enclosure 910. In the inserted position illustrated in FIG. 10B, the thermal management device 120 is disposed in the contact position in which the plungers 170 of the thermal management device 120 are engaged with the vertical sides of computing layer 110 (i.e., IC dies 102) of the chip package 100 of the inserted electronic device 140.

Similar to as described above, the enclosure 910 also includes actuators 950 that move the thermal management devices 120 between the clear and contact positions. The actuators 950 may be a lever, cam, latch, slide, linear actuator, electric motor or other suitable device that can move the plungers 170 of the thermal management device 120 laterally into and out of contact with the vertical sides of the adjacent electronic device 140. In the example depicted in FIGS. 10A and 10B, the actuator 950 is in the form of a cam that can be rotated to move the thermal management device 120 against a spring return force in a direction towards and in contact with the electronic device 140, such as in contact with the computing layer of the chip package 100 of the electronic device 140. When the cam is rotated in the opposite direction, the spring return force moves the thermal management device 120 in a direction away from and out of contact with the electronic device 140, thus enabling the electronic device 140 to move into and out of the enclosure 910 through the slot 980.

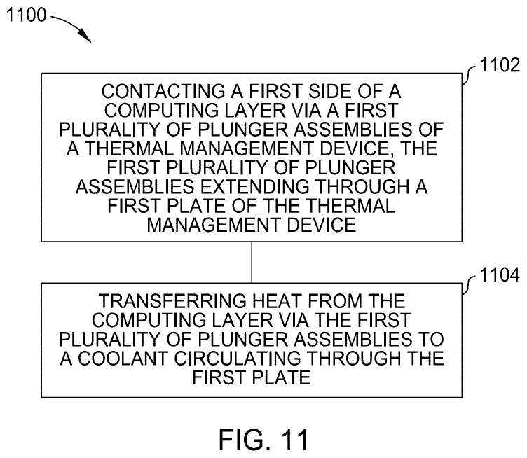

FIG. 11 is a schematic diagram of a method 1100 for cooling an electronic device, such as any of the electronic devices described above, among others. The method for cooling an electronic device begins at operation 1102 by contacting a first side of a computing layer via a first plurality of plunger assemblies extending through a first plate. The method 1100 continues at operation 1104 by transferring heat from the computing layer via the first plurality of plunger assemblies to a coolant circulating through the first plate.

In some examples, the method 1100 may include contacting a second side of the computing layer via a second plurality of plunger assemblies extending through a second plate; and transferring heat from the computing layer via the second plurality of plunger assemblies to a coolant circulating through the second plate. In some examples, power may be delivered to the second side of the computing layer through the second plate.

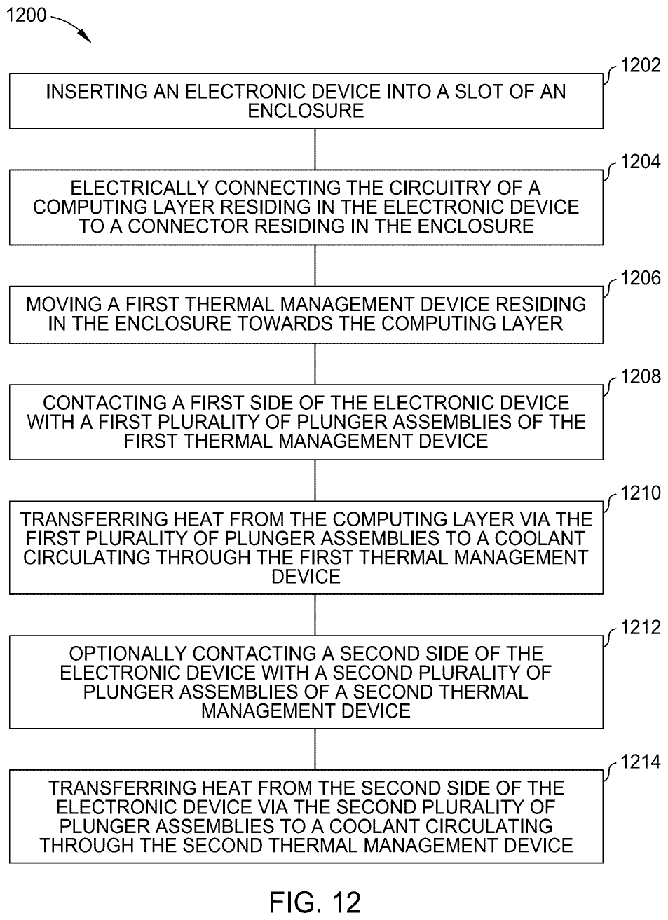

FIG. 12 is a schematic diagram of another method 1200 for cooling an electronic device disposed in an enclosure, such as the enclosure 910 or other suitable enclosure. The method 1200 begins at operation 1202 by inserting an electronic device 140 into a slot 980 of an enclosure 910. One or more other electronic devices 140 may also be inserted into the enclosure 910.

At operation 1204, the circuitry of a computing layer residing in the electronic device 140 is electrically connected to an electrical connector 908 residing in the enclosure 910. In one example, the electrical connector 908 is a socket configured to mate with an edge connector 906 exposed on an edge of the PCB 902 of the electronic device 140.

At operation 1206, a first thermal management device 120 residing in the enclosure is moved towards the computing layer 120 of the fully inserted electronic device 140. The first thermal management device 120 may be moved by any suitable device, such as an actuator 950. In one example, the actuator 950 is a cam that moves the electronic device 140 into engagement with the computing layer 120 of the electronic device 140 as described above.

At operation 1208, a first side of the electronic device 140 contacts a first plurality of plunger assemblies 124 of the first thermal management device 120. At operation 1210, heat is transferred from the computing layer 120 via the first plurality of plunger assemblies 124 to a coolant circulating through the first thermal management device 120. The coolant is provide via an inlet port 924 disposed on the enclosure 910.

At operation 1212, an optional second thermal management device 120 may be moved into contact a second side of the electronic device 140. A second plurality of plunger assemblies 124 of second thermal management device 120 engage one or a second side of the computing layer 120, or a power delivery layer 810 disposed between the computing layer 120 and the second thermal management device 120.

At operation 1214, heat is transferred from the second side of the electronic device 140 via the second plurality of plunger assemblies 170 to a coolant circulating through the second thermal management device 120. The coolant is provide from the same inlet port 924 described above. Coolant exits the thermal management devices 140 through a common outlet port 920.

Thus, a thermal management device and electronic devices having the same have been described herein that provide excellent thermal contact with a large surface area of silicon without creating undesirable amounts mechanical stress. The thermal management device provide efficient heat dissipation while maintaining the structural integrity of the electronic device. Additionally, the thermal management solutions described above are scalable, thus offering exceptional versatility and adaptability. The advantage of this innovative plunger-based thermal solution is the ability to extend the cooling limit of an electronic device, while effectively managing mechanical stresses. Consequently, regardless of the system's size or complexity, the thermal management device can advantageously provide efficient temperature regulation need to employ high powered computing devices without sacrificing performance or reliability.

While the foregoing is directed to embodiments of the present invention, other and further embodiments of the invention may be devised without departing from the basic scope thereof, and the scope thereof is determined by the claims that follow.

What is claimed is:

1. A thermal management device comprising:
a metal plate having a first side and a second side; and
a plurality of plunger assemblies retained to the metal plate, each plunger assembly comprising:
a metal body extending normally through an aperture formed between the first and second sides of the metal plate, the metal body of the plunger assembly movable relative to the metal plate; and
a spring disposed on the first side of the metal plate and operable to bias a distal end of the metal body away from the second side of the metal plate.

2. The thermal management device of claim 1, wherein the metal plate comprises:
a coolant channel routed on or through the metal plate.

3. The thermal management device of claim 2, wherein the coolant channel is routed between two adjacent plunger assemblies of the plurality of plunger assemblies.

4. The thermal management device of claim 3 further comprising:
a flexible heat pipe coupled between the metal plate and one of the plunger assemblies.

5. The thermal management device of claim 3 further comprising:
a heat pipe is embedded in the plunger assembly.

6. The thermal management device of claim 2, wherein the coolant channel is routed in contact with a first plunger assembly of the plunger assemblies.

7. The thermal management device of claim 6, wherein the coolant channel is at least partially embedded in the first plunger assembly.

8. An electronic device comprising:
a computing layer a first side and a second side; and
a first thermal management device disposed adjacent the first side of the computing layer, the first thermal management device comprising:
a first metal plate having a first side and a second side, the second side of the first metal plate disposed adjacent the first side of the computing layer; and
a plurality of first plunger assemblies retained to the first metal plate, each first plunger assembly comprising:
a metal body extending normally through an aperture formed through the first metal plate, the metal body of the first plunger assembly movable relative to the first metal plate; and
a spring biasing a distal end of the metal body away from the second side of the first metal plate and into contact with the first side of the computing layer.

9. The electronic device of claim 8, wherein the computing layer comprises:
a plurality of integrated circuit dies disposed on a substrate, the plurality of integrated circuit dies disposed on the first side of the computing layer and facing the first metal plate.

10. The electronic device of claim 8, wherein the first metal plate comprises:
a coolant channel routed on or through the first metal plate.

11. The electronic device of claim 10, wherein the coolant channel is routed between two adjacent plunger assemblies of the plurality of first plunger assemblies.

12. The electronic device of claim 11 further comprising:
a flexible heat pipe coupled between the first metal plate and a first plunger assembly of the first plunger assemblies.

13. The electronic device of claim 11 further comprising:
a heat pipe is embedded in a first plunger assembly of the first plunger assemblies.

14. The electronic device of claim 10, wherein the coolant channel is routed in contact with a first plunger assembly of the first plunger assemblies.

15. The electronic device of claim 14, wherein the coolant channel is at least partially embedded in the first plunger assembly.

16. The electronic device of claim 8 further comprising:
a second thermal management device disposed adjacent the second side of the computing layer, the second thermal management device comprising:
a second metal plate having a first side and a second side, the first side of the second metal plate facing the second side of the computing layer; and
a plurality of second plunger assemblies retained to the second metal plate, each second plunger assembly comprising:
a metal body extending normally through an aperture formed through the second metal plate, the metal body of the second plunger assembly movable relative to the second metal plate; and
a spring biasing a distal end of the metal body away from a first side of the second metal plate and into contact with the second side of the computing layer.

17. The electronic device of claim 16 further comprising:
a power delivery layer separated from the second side of the computing layer by the second thermal management device, the power delivery layer having a plurality of electrical routings coupled to integrated circuits present in the computing layer through the second thermal management device.

18. The electronic device of claim 16 further comprising:
a signal delivery layer separated from the second side of the computing layer by the second thermal management device, the signal delivery layer having a plurality of electrical routings coupled to integrated circuits present in the computing layer through the second thermal management device.

19. The electronic device of claim 16 further comprising:
a housing having an interior volume accessible via a plurality of slots, the first thermal management device disposed in the interior volume;
an expansion card or service blade disposed through one of the plurality of slots, the expansion card or service blade having the computing layer mounted thereto, the first plunger assemblies configured to engage the computing layer when the expansion card or service blade positioned extends into the interior volume.

20. The electronic device of claim 19 further comprising:
a coolant channel having an inlet and outlet formed in the housing, the coolant channel routed on or through the first metal plate.

21. A method for cooling an electronic device, the method comprising:
contacting a first side of a computing layer via a first plurality of plunger assemblies extending through a first plate; and
transferring heat from the computing layer via the first plurality of plunger assemblies to a coolant circulating through the first plate.

22. The method of claim 21 further comprising:
contacting a second side of the computing layer via a second plurality of plunger assemblies extending through a second plate; and
transferring heat from the computing layer via the second plurality of plunger assemblies to a coolant circulating through the second plate.

23. The method of claim 22 further comprising:
delivery power to the second side of the computing layer through the second plate.
